(19) United States
(12) Patent Application Publication
(10) Pub. No.: US 2026/0150320 A1
(43) Pub. Date: May 28, 2026

(54) SEMICONDUCTOR POWER DEVICE WITH SHIELDING LAYER

(71) Applicant: Huawei Digital Power Technologies Co., Ltd., Shenzhen (CN)

(72) Inventor: Gilberto Curatola, Munich (DE)

(73) Assignee: Huawei Digital Power Technologies Co., Ltd., Shenzhen (CN)

(21) Appl. No.: 19/459,790

(22) Filed: Jan. 26, 2026

Related U.S. Application Data
(63) Continuation of application No. PCT/EP2023/070647, filed on Jul. 25, 2023.

(51) Int. Cl. H10D 30/47; H10D 62/824; H10D 84/01; H10D 84/82; H10W 10/00; H10W 10/17; H10W 10/50

(52) U.S. Cl. CPC H10D 30/474; H10D 30/475; H10D 84/0123; H10D 84/82; H10W 10/051; H10W 10/17; H10W 10/50; H10D 62/824

(57) ABSTRACT

The disclosure relates to a semiconductor power device (100), comprising: a semiconductor substrate (110); a transition layer (111) formed above the semiconductor substrate (110); a Gallium-Nitride, GaN, channel layer (122) formed above the transition layer (111); an Aluminum Gallium-Nitride, AlGaN, barrier layer (130) formed on top of the GaN channel layer (122); a first GaN power device (102) and a second GaN power device (103) formed next to each other in the AlGaN barrier layer (130) and the GaN channel layer (122); and a shielding layer (101) formed between the GaN channel layer (122) and the semiconductor substrate (110). The shielding layer (101) is configured to create a 2-dimensional hole gas, 2DHG, for shielding the first GaN power device (102) and the second GaN power device (103) against an electrical potential of the semiconductor substrate (110).

### CROSS-REFERENCE TO RELATED APPLICATIONS

This application is a continuation of International Application No. PCT/EP2023/070647, filed on Jul. 25, 2023, the disclosure of which is hereby incorporated by reference in its entirety.

### FIELD

The present disclosure relates to the field of semiconductor devices and semiconductor power device applications including Gallium Nitride (GaN) Technology for Semiconductor Power Device Applications. The present disclosure also relates to semiconductor power devices with a shielding layer and to advanced GaN integrated circuit (IC) technology with substrate isolation.

### BACKGROUND

In current power device applications, a monolithic GaN approach is desired, where high-side and low-side transistors are integrated on the same substrate. However, for such a design, multiple problems have been observed. Since the substrate voltage is sensed by both transistors, depending on the switching conditions, this will impact both the high-side and the low-side transistors. For example, when the low-side transistor is in off-state (LS OFF) and the high-side transistor is in on-state (HS ON), and the substrate potential is fixed to the ground level, then a back-gating effect can be experienced by the high-side transistor causing depletion of the 2 DEG (2-dimensional electron gas) in the high-side transistor with consequent performance degradation. On the other side, if the substrate potential is fixed to the output node of the half-bridge, then some issues can be experienced by the low-side transistor (LS ON, HS OFF) due to the positive voltage on the substrate that can induce trapping effects in the low-side transistor with consequent degradation in performance.

### SUMMARY

Various embodiments of the present disclosure include an efficient monolithic GaN design without experiencing the above-described problems.

In particular, the present disclosure provides a new approach and design for a semiconductor power device, in particular in GaN technology without the above-described performance degradation due to back-gating and trapping effects.

Various embodiments of the present disclosure provide a new scheme and technology to obtain the substrate isolation for adjacent GaN power devices. Embodiments of the present disclosure provide for monolithic integration of half-bridge without suffering from substrate bias effects, and simplifying the process complexity of conventional approaches that have been proposed to tackle the issues of substrate bias effects. Embodiments of the present disclosure improve the dynamic effects thanks to the shielding effects obtained thanks to the presence of a 2-dimensional hole gas (2DHG). Embodiments of the present disclosure can be applied to both medium voltage and high voltage device concepts. Embodiments of the present disclosure can be used on both conventional Silicon (Si) substrates and alternative substrates, like SOI (silicon on insulation), sapphire, etc.

Embodiments of the present disclosure enable the successful implementation of monolithically integrated approaches in GaN technology, which is today very challenging.

In order to describe the present disclosure in detail, the following terms, abbreviations and notations will be used:
GaN Gallium Nitride
MOSFET Metal Oxide Semiconductor Field Effect Transistor
2DHG 2-dimensional hole gas
2DEG 2-dimensional electron gas
HEMT high electron mobility transistor
RDSON on-resistance between Drain and Source terminals
HS high-side (of switch)
LS low-side (of switch)
SOI silicon-on-insulator

Silicon-on-insulator (SOI) is a semiconductor wafer technology that produces higher performing, lower power (dynamic) devices than traditional bulk silicon techniques. SOI works by placing a thin, insulating layer, such as silicon oxide between a thin layer of silicon and the silicon substrate.

In the present disclosure, semiconductor power devices in GaN technology are described.

GaN technology for power applications is currently developed by established semiconductor power manufacturers and holds the great promise to possibly replace conventional silicon technology. The main advantages of wide bandgap materials, like Silicon Carbide (SiC) and GaN, is represented by the capability of withstanding higher electric fields, for the same design of a drift region, for example. This translates into the possibility of having smaller power devices with respect to conventional Silicon counterparts. Moreover, wide bandgap material offers smaller device capacitance and the possibility to reach higher switching frequency. The benefits at system level are easily translated into better performance, higher power density, and smaller weight and volume of the overall system.

One key difference of GaN technology, with respect to conventional Silicon technology for power transistors, is represented by the fact that GaN is a lateral technology. It means that Gate, Source, and Drain contact lie on the same surface and the current flows in a lateral direction rather than in a vertical direction like in conventional Silicon Power MOSFETs. Accordingly, the device performance can be adjusted by simply changing the lateral layout but has the drawback that if several devices are implemented, they share the same substrate, and it is very difficult to implement a proper isolation. Even if a lateral isolation is generally implemented between adjacent devices, a proper vertical isolation is generally not available. However, these issues are solved by using a proper shielding layer as described in the present disclosure.

By applying a shielding layer according to the present disclosure, this issue does not limit the possibility to integrate monolithically more than one device in the same chip. Half-bridge integration of high-side and low-side transistors are no more technically challenging when applying such shielding layer according to the present disclosure.

GaN epitaxy approaches can make use of the so called “AlGaN back-barrier” approach, where an AlGaN layer with low Aluminum content (<10%) is grown underneath the GaN channel layer. Due to the presence of the polarization charges, there is the formation of a 2DHG (two-dimensional hole gas) at the interface between the GaN channel and the AlGaN buffer. The AlGaN back-barrier provides the following: 1) positive shift of the threshold voltage (higher positive value of the threshold voltage can be achieved thanks to the presence of the back-barrier); and 2) the presence of a two-dimensional hole gas can have very beneficial effects on minimizing the dynamic effects in GaN technology regarding current collapse and dynamic RDSON.

On the contrary, the main disadvantage of the back-barrier is that the 2DHG is effectively floating. Holes can then move left or right, depending on the applied field and can strongly impact the carrier density and the field distribution in the device. This can have a very strong detrimental impact on the overall device reliability. In the present disclosure, the floating effect of the 2DHG is advantageously utilized to design a shielding layer as described in the present disclosure.

According to a first aspect, the present disclosure relates to a semiconductor power device, comprising: a semiconductor substrate; a transition layer formed above the semiconductor substrate; a Gallium-Nitride (GaN) channel layer formed above the transition layer; an Aluminum Gallium-Nitride (AlGaN) barrier layer formed on top of the GaN channel layer; a first GaN power device and a second GaN power device formed next to each other in the AlGaN barrier layer and the GaN channel layer; and a shielding layer formed between the GaN channel layer and the semiconductor substrate, the shielding layer being configured to create a 2-dimensional hole gas, 2DHG, for shielding the first GaN power device and the second GaN power device against an electrical potential of the semiconductor substrate.

The created two-dimensional hole gas (2DHG) allows shielding of the substrate potential and avoids that this potential will affect either the low-side transistor (first GaN power device) and/or the high-side transistor (second GaN power device).

The 2DHG enables positive shift of the threshold voltage to achieve higher positive value of the threshold voltage. The presence of 2DHG has very beneficial effects on minimizing the dynamic effects in GaN technology such as current collapse and dynamic RDSON.

This new device allows to realize monolithic integration of half-bridge without suffering from substrate bias effects.

Although only a first and a second GaN power device are described here, any number of first and second GaN power devices can be included in the semiconductor power device.

In an exemplary implementation of the semiconductor power device, the semiconductor power device comprises: a lateral isolation block configured to laterally isolate the first GaN power device from the second GaN power device, wherein the lateral isolation block extends deeper into the semiconductor power device than the shielding layer.

The isolation block extends deeper than the “shielding layer.” The reason is to interrupt the 2DHG and therefore to isolate laterally the adjacent devices. Deeper here means that the isolation block is or extends closer to the backside of the substrate (or backside of the semiconductor power device) than the shielding layer. The isolation block is effectively a non-conducting material. It can be a dielectric layer, an amorphous region obtained by high energy damaging implantation or also it can be a trench.

In an exemplary implementation of the semiconductor power device, each one of the first GaN power device and the second GaN power device comprises a source terminal that is electrically connected to the shielding layer. By connecting the source terminal to the shielding layer, the electrical potential of the shielding layer can be efficiently derived to the source terminal.

In an exemplary implementation of the semiconductor power device, each source terminal is connected by a respective plug to the shielding layer, the connection of the respective plug with the shielding layer is configured to shield against bias influences from a backside of the semiconductor substrate. Thus, bias influences from the backside of the semiconductor substrate will have no detrimental impact on the device reliability.

In an exemplary implementation of the semiconductor power device, the semiconductor power device comprises: a trench filled with conductive material to form the respective plug, the trench penetrating the AlGaN barrier layer and the GaN channel layer for providing an electrical connection of the first GaN power device and the second GaN power device to the shielding layer. Such trench or trenches create a low-ohmic connection with the shielding layer and result in an efficient shielding against the electrical potential of the substrate.

In an exemplary implementation of the semiconductor power device, the trench is filled with a metal layer or with a p-type doped GaN layer. Both materials result in a low-ohmic connection with the shielding layer.

In an exemplary implementation of the semiconductor power device, for each GaN power device: i) the source terminal connects a two-dimensional electron gas (2DEG), created at an interface between the GaN channel layer and the AlGaN, barrier layer with an Ohmic contact; ii) the plug connects the 2DHG; and iii) the source terminal and the plug are electrically connected in order to have a same electrical potential. Such a design provides efficient shielding against high potentials at the backside of the substrate.

In an exemplary implementation of the semiconductor power device, the plug is formed as either a pGaN layer or a metal layer. Exemplary metals can be Ni, Au, Pt, Pd, for example.

In an exemplary implementation of the semiconductor power device, the first GaN power device and the second GaN power device are electrically connected with each other to form a high-side switch and a low-side switch of a switching device. Such design allows monolithically integration of high-side switch with low-side switch in the semiconductor power device. Not only can two transistors be integrated, but it should be understood that more than two transistors, e.g., three, four, five, six, seven, eight, nine, ten, eleven, twelve, etc. can be integrated as well.

In an exemplary implementation of the semiconductor power device, the shielding layer is formed at an interface between the GaN channel layer and the transition layer. This is a first possible embodiment where the shielding layer can be located in the semiconductor power device.

In an exemplary implementation of the semiconductor power device, the shielding layer is formed within the transition layer. This is a second possible embodiment where the shielding layer can be located in the semiconductor power device. In this way, a better trade-off can be achieved between the added process complexity and the overall breakdown strength of the devices.

In an exemplary implementation of the semiconductor power device, the semiconductor power device comprises: a nucleation layer formed between the semiconductor substrate and the transition layer; wherein the shielding layer is formed at an interface between the transition layer and the nucleation layer. This is a third possible embodiment where the shielding layer can be located in the semiconductor power device.

In an exemplary implementation of the semiconductor power device, the semiconductor substrate comprises a Silicon substrate or a Silicon-on-Insulator substrate. The Silicon-on-Insulator substrate provides overall immunity to the substrate bias. Alternatively, sapphire substrates, QST substrates, etc. can also be used.

In an exemplary implementation of the semiconductor power device, the first GaN power device and the second GaN power device are monolithically integrated on the same semiconductor substrate. By such monolithically integration, the dimensions of the power device can be reduced.

In an exemplary implementation of the semiconductor power device, the semiconductor power device comprises: a first main surface and a second main surface arranged on opposite sides of the semiconductor power device; wherein each of the first GaN power device and the second GaN power device comprises a Gate terminal, a Source terminal and a Drain terminal which are arranged on either the first main surface or the second main surface of the semiconductor power device. Accordingly, the device performance can be adjusted by simply changing the lateral layout.

According to a second aspect, the disclosure relates to a method for producing a semiconductor power device, the method comprising: providing a semiconductor substrate; forming a transition layer above the substrate; forming a Gallium-Nitride (GaN) channel layer above the transition layer; forming an Aluminum Gallium-Nitride (AlGaN) barrier layer on top of the GaN channel layer; forming a first GaN power device and a second GaN power device next to each other in the AlGaN barrier layer and the GaN channel layer; and forming a shielding layer between the GaN channel layer and the semiconductor substrate, the shielding layer being configured to create a 2-dimensional hole gas, 2DHG, for shielding the first GaN power device and the second GaN power device against an electrical potential of the semiconductor substrate.

This new method allows for monolithic integration of a half-bridge without suffering from substrate bias effects. It also allows for simplifying the process complexity.

The newly created two-dimensional hole gas (2DHG) allows to shield the substrate potential and avoid that this potential will affect either the low-side transistor (first GaN power device) and/or the high-side transistor (second GaN power device).

### BRIEF DESCRIPTION OF THE DRAWINGS

Further embodiments of the present disclosure will be described with respect to the following figures, in which:

FIG. 1 shows a schematic cross section of a first embodiment of a semiconductor power device, according to the present disclosure;

FIG. 2 shows a schematic cross section of a second embodiment of a semiconductor power device, according to the present disclosure;

FIG. 3 shows a schematic cross section of a third embodiment of a semiconductor power device, according to the present disclosure;

FIG. 4 shows a schematic cross section of a fourth embodiment of a semiconductor power device, according to the present disclosure;

FIG. 5 shows a schematic cross section of a fifth embodiment of a semiconductor power device, according to the present disclosure; and

FIG. 6 shows a schematic diagram illustrating a method 600 for producing a semiconductor power device, according to the present disclosure.

### DETAILED DESCRIPTION

In the following detailed description, reference is made to the accompanying drawings, which form a part thereof, and in which is shown by way of illustration specific aspects in which the present disclosure may be practiced. It is understood that other aspects may be utilized and structural or logical changes may be made without departing from the scope of the present disclosure. The following detailed description, therefore, is not to be taken in a limiting sense, and the scope of the present disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

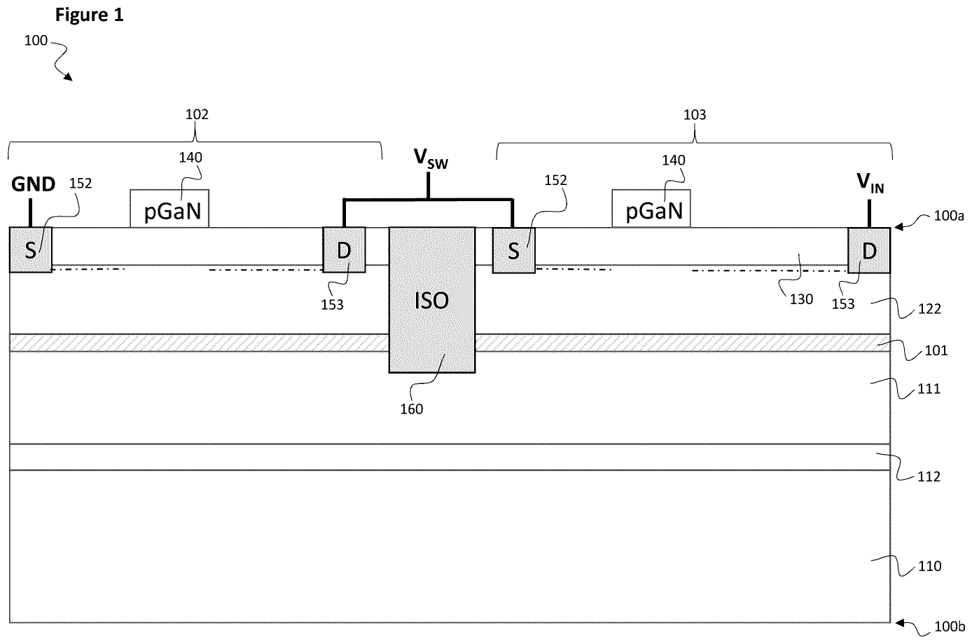

FIG. 1 shows a schematic cross section of a first embodiment of a semiconductor power device 100, according to the present disclosure.

The semiconductor power device 100 comprises: a semiconductor substrate 110; a transition layer 111 formed above the semiconductor substrate 110; a nucleation layer 112 formed between the semiconductor substrate 110 and the transition layer 111; a Gallium-Nitride (GaN) channel layer 122 formed above the transition layer 111; an Aluminum Gallium-Nitride (AlGaN) barrier layer 130 formed on top of the GaN channel layer 122; a first GaN power device 102 (e.g., a low-side transistor) and a second GaN power device 103 (e.g., a high-side transistor) formed next to each other in the AlGaN barrier layer 130 and the GaN channel layer 122; and a shielding layer 101 formed between the GaN channel layer 122 and the semiconductor substrate 110. The shielding layer 101 is configured to create a 2-dimensional hole gas (2DHG) for shielding the first GaN power device 102 and the second GaN power device 103 against an electrical potential of the semiconductor substrate 110.

This newly created two-dimensional hole gas (2DHG) will allow for shielding the substrate potential and avoid that this potential will affect either the low-side transistor (first GaN power device 102) and/or the high-side transistor (second GaN power device 103).

The 2DHG enables positive shift of the threshold voltage to achieve higher positive value of the threshold voltage. The presence of 2DHG has very beneficial effects on minimizing the dynamic effects in GaN technology (current collapse, dynamic RDSON).

This new device allows for monolithic integration of a half-bridge without suffering from substrate bias effects. It also allows for simplifying the process complexity.

Although only a first and a second GaN power device are described here, any number of first and second GaN power devices can be included in the semiconductor power device.

FIG. 1 shows a new design for a new epitaxial layer that allows for overcoming the previously explained issues. In particular, a new isolation layer, named hereinafter as shielding layer with reference sign 101 is inserted between the GaN channel 122 and the transition layer 111. The main role of this shielding layer 101 is to create a strong 2DHG gas between the GaN channel 122 and the transition layer 111. This newly created two-dimensional hole gas will allow to shield the substrate potential and avoid that this potential will affect either the low-side transistor 102 and/or the high-side transistor 103.

The semiconductor power device 100 may comprise a lateral isolation block 160 configured to laterally isolate the first GaN power device 102 from the second GaN power device 103. As shown in FIG. 1, the lateral isolation block 160 extends deeper into the semiconductor power device 100 (in the direction from the top surface 100a to the bottom surface 100b of the device 100) than the shielding layer 101.

The isolation block 160 extends deeper than the shielding layer 101. The reason is to interrupt the 2DHG and therefore to isolate laterally the adjacent devices. Deeper means here that the isolation block 160 is or extends closer to the backside 100b of the substrate 110 (or backside 100b of the semiconductor power device) than the shielding layer 101.

The isolation block 160 is effectively a non-conducting material. It can be a dielectric layer, an amorphous region obtained by high energy damaging implantation, or also it can be a trench.

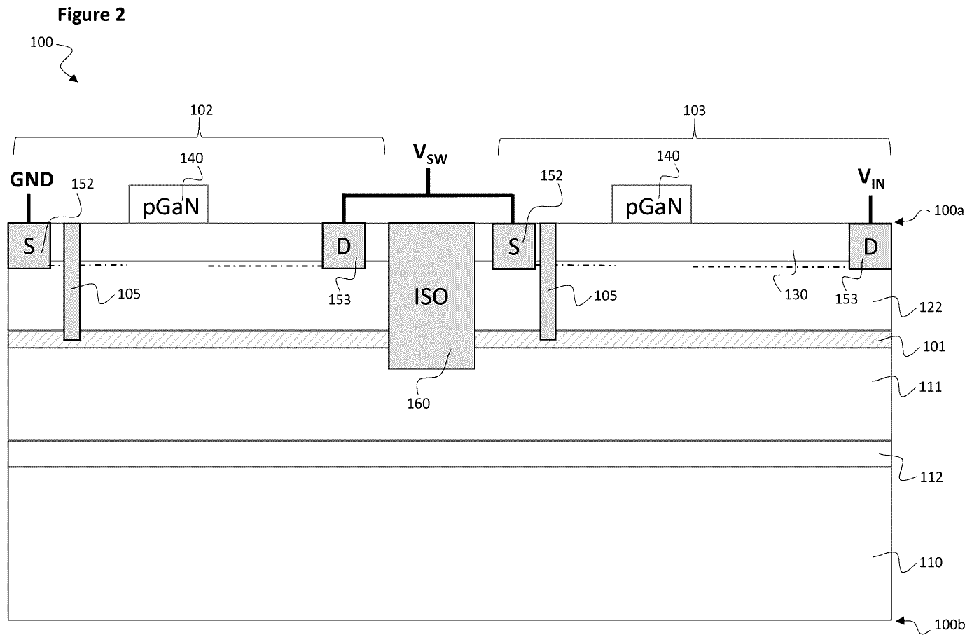

Each one of the first GaN power device 102 and the second GaN power device 103 may comprise a source terminal 152 that is electrically connected (shown in FIGS. 2 to 5) to the shielding layer 101.

FIG. 2 shows a schematic cross section of a second embodiment of a semiconductor power device 100, according to the present disclosure.

The design of the semiconductor power device 100 shown in FIG. 2 is analogous to the design shown in FIG. 1, however, additional plugs 105 or trenches 105 are formed in the device 100.

FIG. 2 shows the final product where both the low-side and high-side transistors 102, 103 are both connected to this shielding layer 101. In particular, the source terminal 152 of both the HS and LS transistors 103, 102 are connected to the shielding layer 101. In particular, trenches 105 are opened to the source side of both transistors 102, 103 and, then, the trenches 105 are filled with metal layers (or highly p-type doped GaN layer) in order to create a low-ohmic connection with the shielding layer 101.

In the design of the semiconductor power device 100 shown in FIG. 2, each source terminal 152 is connected by a respective plug 105 to the shielding layer 101. The connection of the respective plug 105 with the shielding layer 101 is configured to shield against bias influences from a backside 100b of the semiconductor substrate 110.

As described above, the semiconductor power device 100 comprises a trench 105 filled with conductive material to form the respective plug 105. The trench 105 is penetrating the AlGaN barrier layer 130 and the GaN channel layer 122 for providing an electrical connection of the first GaN power device 102 and the second GaN power device 103 to the shielding layer 101.

The trench 105 can be filled either with a metal layer or with a p-type doped GaN layer.

For each GaN power device 102, 103: the source terminal 152 connects a two-dimensional electron gas (2DEG) created at an interface between the GaN channel layer 122 and the AlGaN, barrier layer 130 with an Ohmic contact; the plug 105 connects the 2DHG; and the source terminal 152 and the plug 105 are electrically connected in order to have a same electrical potential.

As described above with respect to the trench, the plug 105 created by the trench may be formed as either a pGaN layer or a metal layer.

Exemplary metals can be Ni, Au, Pt, Pd, for example.

The first GaN power device 102 and the second GaN power device 103 can be electrically connected with each other to form a high-side switch and a low-side switch of a switching device. As described above, more than two GaN power devices may be integrated in the semiconductor power device 100. For example, a switch may be formed by more than two such GaN power devices or multiple switches may be integrated in this semiconductor power device 100.

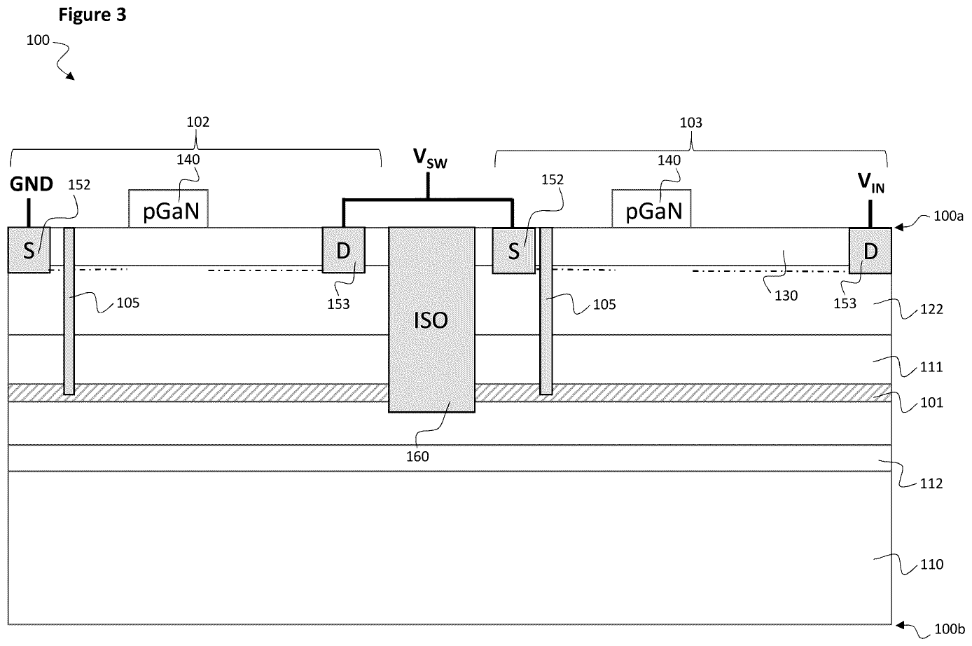

As shown in FIG. 2, the shielding layer 101 may be formed at an interface between the GaN channel layer 122 and the transition layer 111. Other locations for the shielding layer 101 can be implemented as well, e.g., as described below with respect to FIGS. 3 to 5.

As shown in FIG. 2 (and other Figures), the first GaN power device 102 and the second GaN power device 103 can be monolithically integrated on the same semiconductor substrate 110.

As shown in FIG. 2, the semiconductor power device 100 comprises: a first main surface 100a and a second main surface 100b arranged on opposite sides of the semiconductor power device 100.

As shown in FIG. 2, each of the first GaN power device 102 and the second GaN power device 103 comprises a Gate terminal 140, a Source terminal 152, and a Drain terminal 153 which may be arranged on either the first main surface 100a or the second main surface 100b of the semiconductor power device 100. Accordingly, the device performance can be adjusted by simply changing the lateral layout.

FIG. 3 shows a schematic cross section of a third embodiment of a semiconductor power device 100, according to the present disclosure.

The design of the semiconductor power device 100 shown in FIG. 3 is analogous to the design shown in FIG. 1, however, additional plugs 105 or trenches 105 are formed in the device 100.

A further difference to the devices shown in FIGS. 1 and 2 is the location of the shielding layer 101.

In the device 100 shown in FIG. 3, the shielding layer 101 is formed within the transition layer 111.

The shielding layer 101 may be inserted in the middle of the transition layer 111 rather than at the interface between the GaN channel 122 and the transition layer 111. This approach allows for a better trade-off between the added process complexity and the overall breakdown strength of the devices.

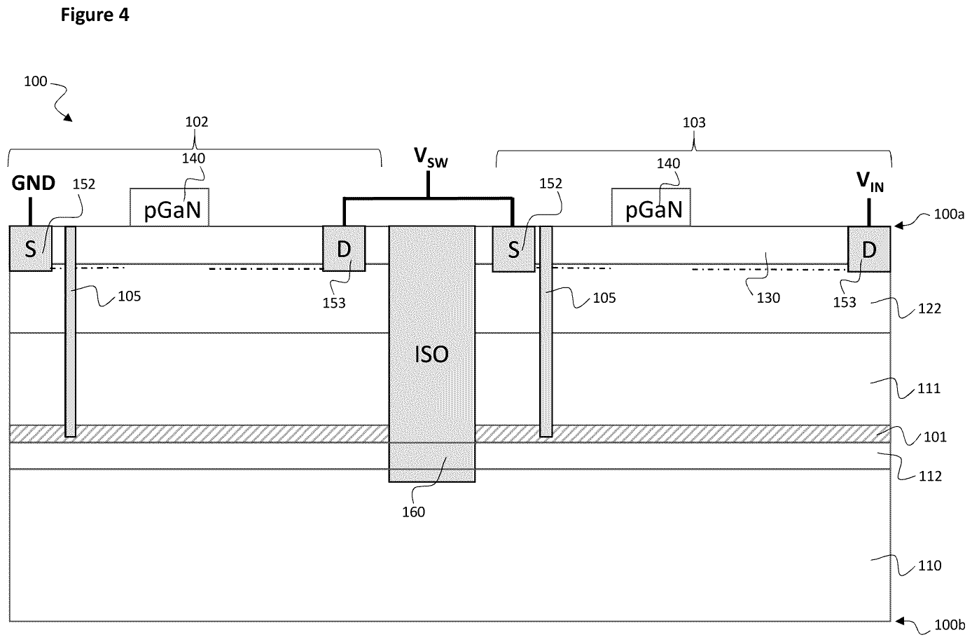

FIG. 4 shows a schematic cross section of a fourth embodiment of a semiconductor power device 100, according to the present disclosure.

The design of the semiconductor power device 100 shown in FIG. 4 is analogous to the design shown in FIG. 1, however, additional plugs 105 or trenches 105 are formed in the device 100.

A further difference to the devices shown in FIGS. 1 and 2 is the location of the shielding layer 101.

In the device 100 shown in FIG. 4, a nucleation layer 112 is formed between the semiconductor substrate 110 and the transition layer 111. The shielding layer 101 is formed at an interface between the transition layer 111 and the nucleation layer 112.

Thus, FIG. 4 provides an alternative embodiment where the shielding layer 101 is placed at the interface between the transition layer 111 and the nucleation layer 112.

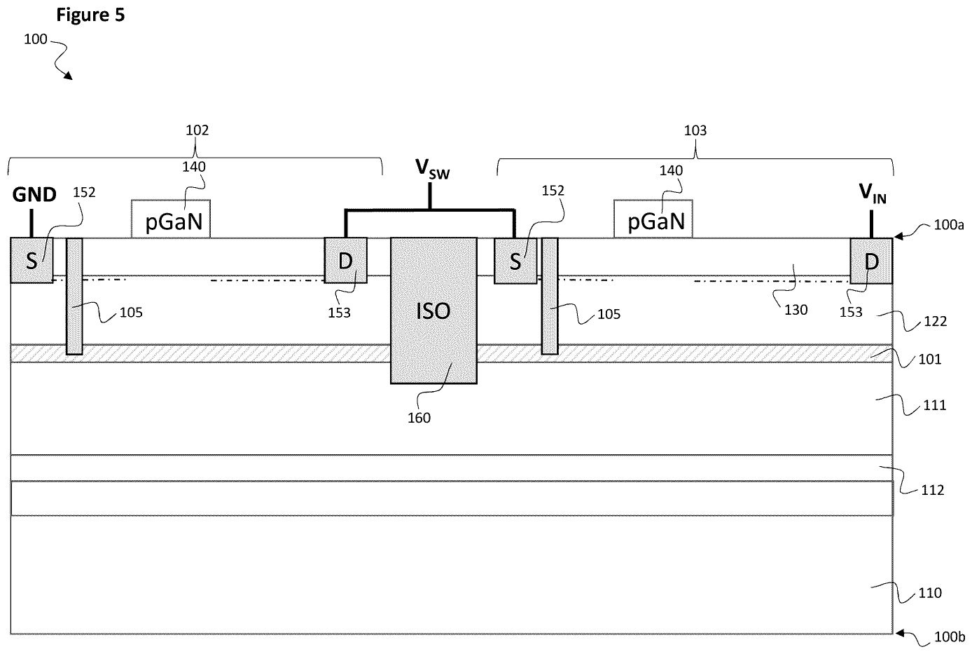

FIG. 5 shows a schematic cross section of a fifth embodiment of a semiconductor power device 100, according to the present disclosure.

The design of the semiconductor power device 100 shown in FIG. 5 is analogous to the design shown in FIG. 1, however, additional plugs 105 or trenches 105 are formed in the device 100.

A further difference to the devices shown in FIGS. 1 to 4 is that the semiconductor substrate 110 may comprise a Silicon substrate or a Silicon-on-Insulator substrate.

Alternative Silicon substrates are also compatible with the solution presented in the present disclosure. For example, FIG. 5 shows a solution where the standard Si substrate can be replaced with a Silicon-on-Insulator substrate 110. The Silicon-on-Insulator substrate provides overall immunity to the substrate bias. Alternatively, sapphire substrates, QST substrates, etc. can also be used.

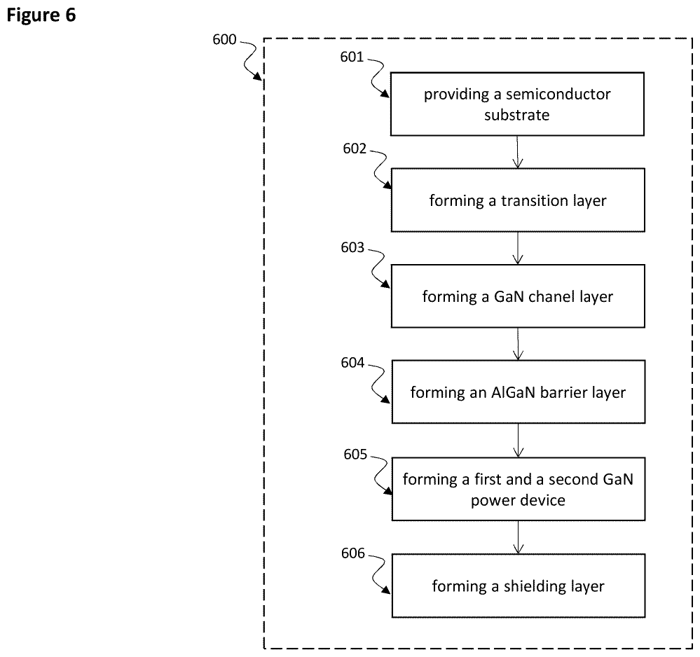

FIG. 6 shows a schematic diagram illustrating a method 600 for producing a semiconductor power device 100, according to the present disclosure.

The method 600 comprises: providing 601 a semiconductor substrate 110, e.g., as shown in FIGS. 1 to 5.

The method 600 comprises: forming 602 a transition layer 111 above the substrate 110, e.g., as shown in FIGS. 1 to 5.

The method 600 comprises: forming 603 a Gallium-Nitride, GaN, channel layer 122 above the transition layer 111, e.g., as shown in FIGS. 1 to 5.

The method 600 comprises: forming 604 an Aluminum Gallium-Nitride, AlGaN, barrier layer 130 on top of the GaN channel layer 122, e.g., as shown in FIGS. 1 to 5.

The method 600 comprises: forming 605 a first GaN power device 102 and a second GaN power device 103 next to each other in the AlGaN barrier layer 130 and the GaN channel layer 122, e.g., as shown in FIGS. 1 to 5.

The method 600 comprises: forming 606 a shielding layer 101 between the GaN channel layer 122 and the semiconductor substrate 110, e.g., as shown in FIGS. 1 to 5, the shielding layer 101 being configured to create a 2-dimensional hole gas (2DHG) for shielding the first GaN power device 102 and the second GaN power device 103 against an electrical potential of the semiconductor substrate 110.

While a particular feature or aspect of the present disclosure may have been disclosed with respect to only one of several implementations, such feature or aspect may be combined with one or more other features or aspects of the other implementations as may be desired and advantageous for any given or particular application. Furthermore, to the extent that the terms “include,” “have,” “with,” or other variants thereof are used in either the detailed description or the claims, such terms are intended to be inclusive in a manner similar to the term “comprise.” Also, the terms “exemplary,” “for example,” and “e.g.,” are merely meant as an example, rather than the best or optimal. The terms “coupled” and “connected,” along with derivatives may have been used. It should be understood that these terms may have been used to indicate that two elements cooperate or interact with each other regardless whether they are in direct physical or electrical contact, or they are not in direct contact with each other. In the claims as well as in the description the word “comprising” does not exclude other elements or steps and the indefinite article “a” or “an” does not exclude a plurality.

Although specific aspects have been illustrated and described herein, it will be appreciated by those of ordinary skill in the art that a variety of alternate and/or equivalent implementations may be substituted for the specific aspects shown and described without departing from the scope of the present disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the present disclosure has been described with reference to one or more particular embodiments, those skilled in the art recognize that many changes may be made thereto without departing from the scope of the present disclosure. It is therefore to be understood that within the scope of the appended claims and their equivalents, the present disclosure may be practiced otherwise than as specifically described herein.

What is claimed is:

1. A semiconductor power device (100), comprising:
a semiconductor substrate (110);
a transition layer (111) formed above the semiconductor substrate (110);
a Gallium-Nitride, GaN, channel layer (122) formed above the transition layer (111);
an Aluminum Gallium-Nitride, AlGaN, barrier layer (130) formed on top of the GaN channel layer (122);
a first GaN power device (102) and a second GaN power device (103) formed next to each other in the AlGaN barrier layer (130) and the GaN channel layer (122); and
a shielding layer (101) formed between the GaN channel layer (122) and the semiconductor substrate (110), the shielding layer (101) being configured to create a 2-dimensional hole gas, 2DHG, for shielding the first GaN power device (102) and the second GaN power device (103) against an electrical potential of the semiconductor substrate (110).

2. The semiconductor power device (100) of claim 1, comprising:
a lateral isolation block (160) configured to laterally isolate the first GaN power device (102) from the second GaN power device (103),
wherein the lateral isolation block (160) extends deeper into the semiconductor power device (100) than the shielding layer (101).

3. The semiconductor power device (100) of claim 1,
wherein each one of the first GaN power device (102) and the second GaN power device (103) comprises a source terminal (152) that is electrically connected to the shielding layer (101).

4. The semiconductor power device (100) of claim 2,
wherein each one of the first GaN power device (102) and the second GaN power device (103) comprises a source terminal (152) that is electrically connected to the shielding layer (101).

5. The semiconductor power device (100) of claim 3,
wherein each source terminal (152) is connected by a respective plug (105) to the shielding layer (101), the connection of the respective plug (105) with the shielding layer (101) being configured to shield against bias influences from a backside (100b) of the semiconductor substrate (110).

6. The semiconductor power device (100) of claim 4,
wherein each source terminal (152) is connected by a respective plug (105) to the shielding layer (101), the connection of the respective plug (105) with the shielding layer (101) being configured to shield against bias influences from a backside (100b) of the semiconductor substrate (110).

7. The semiconductor power device (100) of claim 5, comprising:
a trench (105) filled with conductive material to form the respective plug (105), the trench (105) penetrating the AlGaN barrier layer (130) and the GaN channel layer (122) for providing an electrical connection of the first GaN power device (102) and the second GaN power device (103) to the shielding layer (101).

8. The semiconductor power device (100) of claim 5, wherein for each GaN power device (102, 103):
the source terminal (152) connects a two-dimensional electron gas, 2DEG, created at an interface between the GaN channel layer (122) and the AlGaN, barrier layer (130) with an Ohmic contact;
the plug (105) connects the 2DHG;
the source terminal (152) and the plug (105) are electrically connected in order to have a same electrical potential.

9. The semiconductor power device (100) of claim 7, wherein for each GaN power device (102, 103):
the source terminal (152) connects a two-dimensional electron gas, 2DEG, created at an interface between the GaN channel layer (122) and the AlGaN, barrier layer (130) with an Ohmic contact;
the plug (105) connects the 2DHG;
the source terminal (152) and the plug (105) are electrically connected in order to have a same electrical potential.

10. The semiconductor power device (100) of claim 8,
wherein the plug (105) is formed as either a pGaN layer or a metal layer.

11. The semiconductor power device (100) of claim 1,
wherein the first GaN power device (102) and the second GaN power device (103) are electrically connected with each other to form a high-side switch and a low-side switch of a switching device.

12. The semiconductor power device (100) of claim 2,
wherein the first GaN power device (102) and the second GaN power device (103) are electrically connected with each other to form a high-side switch and a low-side switch of a switching device.

13. The semiconductor power device (100) of claim 1,
wherein the shielding layer (101) is formed at an interface between the GaN channel layer (122) and the transition layer (111).

14. The semiconductor power device (100) of claim 2,
wherein the shielding layer (101) is formed at an interface between the GaN channel layer (122) and the transition layer (111).

15. The semiconductor power device (100) of claim 1,
wherein the shielding layer (101) is formed within the transition layer (111).

16. The semiconductor power device (100) of claim 1, comprising:
a nucleation layer (112) formed between the semiconductor substrate (110) and the transition layer (111);
wherein the shielding layer (101) is formed at an interface between the transition layer (111) and the nucleation layer (112).

17. The semiconductor power device (100) of claim 1,
wherein the semiconductor substrate (110) comprises a Silicon substrate or a Silicon-on-Insulator substrate.

18. The semiconductor power device (100) of claim 1,
wherein the first GaN power device (102) and the second GaN power device (103) are monolithically integrated on the same semiconductor substrate (110).

19. The semiconductor power device (100) of claim 1, comprising:
a first main surface (100a) and a second main surface (100b) arranged on opposite sides of the semiconductor power device (100);
wherein each of the first GaN power device (102) and the second GaN power device (103) comprises a Gate terminal (140), a Source terminal (152) and a Drain terminal (153) which are arranged on either the first main surface (100a) or the second main surface (100b) of the semiconductor power device (100).

20. A method (600) for producing a semiconductor power device (100), the method comprising:
providing (601) a semiconductor substrate (110);
forming (602) a transition layer (111) above the substrate (110);
forming (603) a Gallium-Nitride, GaN, channel layer (122) above the transition layer (111);
forming (604) an Aluminum Gallium-Nitride, AlGaN, barrier layer (130) on top of the GaN channel layer (122);
forming (605) a first GaN power device (102) and a second GaN power device (103) next to each other in the AlGaN barrier layer (130) and the GaN channel layer (122); and
forming (606) a shielding layer (101) between the GaN channel layer (122) and the semiconductor substrate (110), the shielding layer (101) being configured to create a 2-dimensional hole gas, 2DHG, for shielding the first GaN power device (102) and the second GaN power device (103) against an electrical potential of the semiconductor substrate (110).
